(19) United States
(12) Patent Application Publication
(10) Pub. No.: US 2007/0293032 A1
(43) Pub. Date: Dec. 20, 2007

(54) Semiconductor manufacturing apparatus and semiconductor device manufacturing method

(75) Inventor: Tomohiro Kamimura, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kanagawa (JP)

(21) Appl. No.: 11/808,859

(22) Filed: Jun. 13, 2007

(30) Foreign Application Priority Data
Jun. 14, 2006 (JP) 2006-164183

(51) Int. Cl. H01L 21/44

(52) U.S. Cl. 438/597

(57) ABSTRACT

A semiconductor manufacturing apparatus includes a controller, a wafer stage and an optical unit. The wafer stage is configured to move a semiconductor wafer. The optical unit is configured to expose a first resist film in each of shots of the semiconductor wafer by using a first mask pattern and to expose a second resist film in of the shot by using a second mask pattern. The first mask pattern includes a first interconnection mask pattern and a first identification mask pattern. The second mask pattern includes a second interconnection mask pattern and a second identification mask pattern. A first interconnection metal pattern corresponding to the first interconnection mask pattern and a first identification pattern corresponding to the first identification mask pattern are formed in the first resist film. A second interconnection metal pattern corresponding to the second interconnection mask pattern and a second identification pattern corresponding to the second identification mask pattern are formed in the second resist film. The controller is configured to control the wafer stage and the optical unit such that an offset between the first identification pattern and the second identification pattern is different among the shots based on a predetermined rule.

### BACKGROUND OF THE INVENTION

1. Field of the Invention

The present invention relates to a semiconductor manufacturing apparatus and semiconductor device manufacturing method.

2. Description of Related Art

A semiconductor device manufacturing method generally includes a wafer processing step, assembly step and inspection step. In the wafer processing step, semiconductor elements and interconnections connecting between one and another of the elements are formed in a semiconductor wafer. In the assembly step, the semiconductor wafer is cut into chips. Each of the chips is molded in a case to complete a semiconductor device. The chips may be called as pellets. In the inspection step, a reliability of each semiconductor device is evaluated for selecting non-defective semiconductor devices.

A semiconductor exposure apparatus is disclosed in Japanese Laid Open patent Application (JP-A-Heisei10-144579). The semiconductor exposure apparatus includes a liquid crystal mask which controls a pattern of light passing through the mask. Thus, the semiconductor exposure apparatus can be used for forming a different identification mark in each shot of a semiconductor wafer in the wafer processing step. Here, the shots and chips cut from the wafer have one-to-one correspondence.

Thus, a position in the wafer of the shot corresponding to the chip determined as defective in the inspection step can be identified based on the identification mark. Accordingly, a cause of the defective can be identified based on information obtained in the inspection step.

Other arts for forming a different identification mark in each shot are disclosed in Japanese Laid Open patent Applications (JP-P2001-274067A, JP-A-Heisei1-99051 and JP-A-Heisei7-122479).

The present inventor has recognized that there is a room for reducing a cost or number of steps in the arts for forming a different identification mark in each shot.

### SUMMARY

In one embodiment, a semiconductor manufacturing apparatus includes a controller, a wafer stage and an optical unit. The wafer stage is configured to move a semiconductor wafer. The optical unit is configured to expose a first resist film in each of shots of the semiconductor wafer by using a first mask pattern and to expose a second resist film in the shot by using a second mask pattern. The first mask pattern includes a first interconnection mask pattern and a first identification mask pattern. The second mask pattern includes a second interconnection mask pattern and a second identification mask pattern. A first interconnection metal pattern corresponding to the first interconnection mask pattern and a first identification pattern corresponding to the first identification mask pattern are formed in the first resist film. A second interconnection metal pattern corresponding to the second interconnection mask pattern and a second identification pattern corresponding to the second identification mask pattern are formed in the second resist film. The controller is configured to control the wafer stage and the optical unit such that an offset between the first identification pattern and the second identification pattern is different among the shots based on a predetermined rule.

In another embodiment, a semiconductor device manufacturing method includes exposing a first resist film in each of shots of a semiconductor wafer by using a first mask pattern and exposing a second resist film in the shot by using a second mask pattern. The first mask pattern includes a first interconnection mask pattern and a first identification mask pattern. The second mask pattern includes a second interconnection mask pattern and a second identification mask pattern. A first interconnection metal pattern corresponding to the first interconnection mask pattern and a first identification pattern corresponding to the first identification mask pattern are formed in the first resist film in the exposing the first resist film. A second interconnection metal pattern corresponding to the second interconnection mask pattern and a second identification pattern corresponding to the second identification mask pattern are formed in the second resist film in the exposing the second resist film. An offset between the first identification pattern and second identification pattern is different among the shots based on a predetermined rule.

In further another embodiment, a semiconductor manufacturing apparatus includes a means for moving a semiconductor wafer, a means for exposing the semiconductor wafer and a means for controlling the means for moving and means for exposing. The means for exposing is configured to expose a first resist film in each of shots of the semiconductor wafer by using a first mask pattern and to expose a second resist film in the shot by using a second mask pattern. The first mask pattern includes a first interconnection mask pattern and a first identification mask pattern. The second mask pattern includes a second interconnection mask pattern and a second identification mask pattern. A first interconnection metal pattern corresponding to the first interconnection mask pattern and a first identification pattern corresponding to the first identification mask pattern are formed in the first resist film. A second interconnection metal pattern corresponding to the second interconnection mask pattern and a second identification pattern corresponding to the second identification mask pattern are formed in the second resist film. The means for controlling is configured to control the means for moving and the means for exposing such that an offset between the first identification pattern and the second identification pattern is different among the shots based on a predetermined rule.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a schematic diagram of a semiconductor manufacturing apparatus according to a first embodiment;

FIG. 2 is a perspective view of an optical unit of the semiconductor manufacturing apparatus according to the first embodiment;

FIG. 3 is a plan view of masks;

FIG. 4 is a plan view of a light-shielding plate;

FIG. 5 is a plan view of another light-shielding plate;

FIG. 6 is a plan view of a semiconductor wafer;

FIG. 7 shows time series variation of a shot of the semiconductor wafer in a semiconductor device manufacturing method according to the first embodiment;

FIG. 8 is a plan view of an example of identification marks;

FIG. 9 is a plan view of another example of identification marks; and

FIG. 10 shows time series variation of a shot of the semiconductor wafer in a semiconductor device manufacturing method according to a second embodiment of the present invention.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

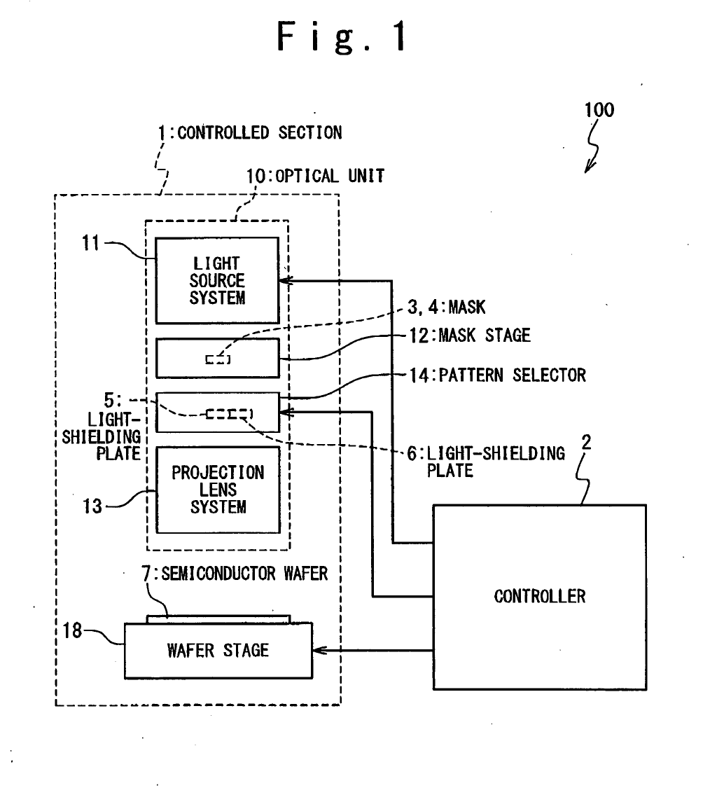

FIG. 1 shows a semiconductor manufacturing apparatus 100 according to a first embodiment of the present invention. The semiconductor manufacturing apparatus 100 includes a controlled section 1 and controller 2 which controls the controlled section 1. The controlled section 1 includes a wafer stage 18 and optical unit 10. The wafer stage 18 supports and moves a semiconductor wafer 7. The optical unit 10 exposes the semiconductor wafer 7. The optical unit 10 includes a light source system 11, mask stage 12, projection lens system 13 and pattern selector 14. The mask stage 12 mounts a mask 3 and mask 4. The pattern selector 14 includes a light-shielding plate 5 and light-shielding plate 6.

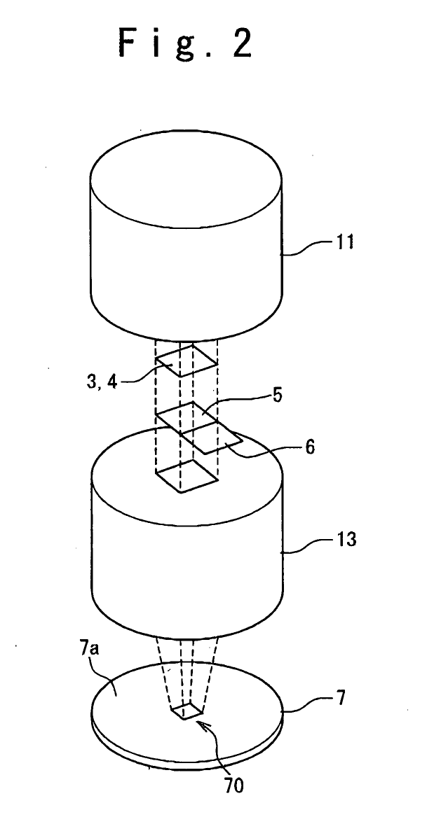

FIG. 2 shows an optical unit of the semiconductor manufacturing apparatus 100. The optical unit 10 exposes each shot 70 of the semiconductor wafer 7 with light which is emitted from the light source system 11 and passes through one of the masks 3 and 4, pattern selector 14 and projection lens system 13.

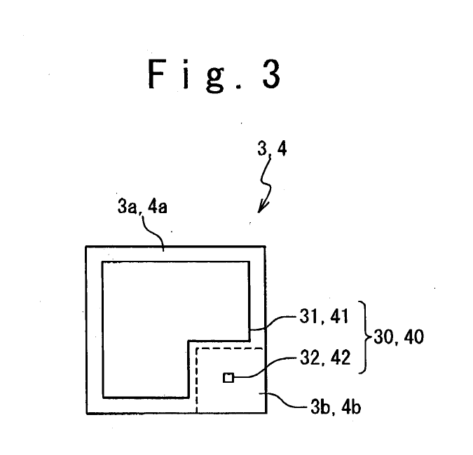

FIG. 3 shows a plan view of the mask 3 and mask 4. The mask 3 includes a mask pattern 30. The mask pattern 30 includes an interconnection metal pattern 31 and identification pattern 32. The interconnection metal pattern 31 is arranged in a first region 3a. The identification pattern 32 is arranged in a second region 3b. The first region 3a is a portion of the mask 3 and the second region 3b is another portion of the mask 3. Similarly, the mask 4 includes a mask pattern 40. The mask pattern 40 includes an interconnection metal pattern 41 and identification pattern 42. The interconnection metal pattern 41 is arranged in a first region 4a. The identification pattern 42 is arranged in a second region 4b. The first region 4a is a portion of the mask 4 and the second region 4b is another portion of the mask 4.

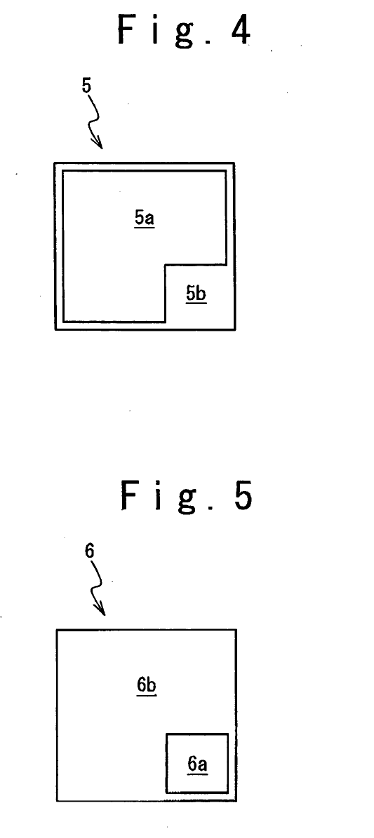

FIG. 4 shows a plan view of the light-shielding plate 5. The light-shielding plate 5 includes a translucent portion 5a and light-shielding portion 5b. The translucent portion 5a permits light passing through itself. But the light-shielding portion 5b does not permit light passing through itself.

FIG. 5 shows a plan view of the light-shielding plate 6. The light-shielding plate 6 includes a translucent portion 6a and light-shielding portion 6b. The translucent portion 6a permits light passing through itself. But the light-shielding portion 6b does not permit light passing through itself.

The controller 2 controls the pattern selector 14 to arrange the one of the light-shielding plates 5 and 6 in an optical path between the light source system 11 and the projection lens system 13, or to arrange neither of the light-shielding plate 5 nor light-shielding plate 6 in the optical path. The optical unit 10 can project the whole of mask pattern 30 onto one of the shots 70 at a timing and project the whole of mask pattern 40 onto one of the shots 70 at a timing. The optical unit 10 can project the interconnection metal pattern 41 alone and identification pattern 42 alone at different timings onto one of the shots 70.

The pattern selector 14 is preferably arranged between the mask stage 12 and projection lens system 13. The pattern selector 14 may be arranged between the light source system 11 and mask stage 12.

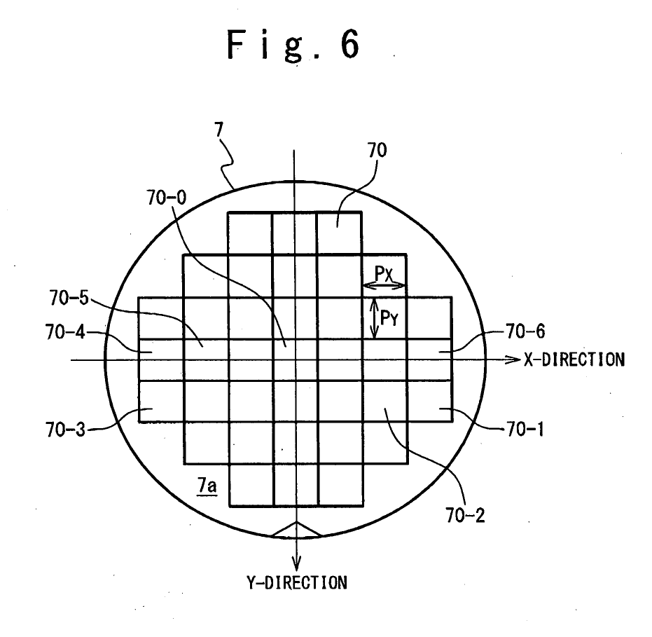

FIG. 6 shows a plan view of the semiconductor wafer 7. The semiconductor wafer 7 is cut from a semiconductor ingot. An X-direction and Y-direction are defined for the semiconductor wafer 7. The X-direction and Y-direction are parallel to a surface 7a of the wafer 7 and are perpendicular to each other. The shots 70 and chips cut from the wafer 7 have one-to-one correspondence. The shots 70 are arranged in a matrix array having rows along the X-direction and columns along the Y-direction. In the rows, the shots 70 are arranged with pitch PX. In the columns, the shots 70 are arranged with pitch PY.

Each of shots 70-0 to 70-6 is one of the shots 70. The shots 70-1 to 70-3 are arranged in a row. The shot 70-1 is arranged in the front position (according to the X-direction) in the row. The shot 70-2 is arranged next to the shot 70-1. The shot 70-3 is arranged in the rear position (according to the X-direction) in the row. The row of shots 70-1 to 70-3 is next to another row in which the shot 70-0 and shots 70-4 to 70-6 are arranged. The row of shots 70-1 to 70-3 is in front (according to the Y-direction) of the row of shot 70-0 and shots 70-4 to 70-6. The shot 70-4 is arranged in the rear position (according to the X-direction) in the row. The shot 70-5 is arranged next to the shot 70-4. The shot 70-6 is arranged in the front position (according to the X-direction) in the row. The shot 70-0 is arranged between the shots 70-5 and 70-6. The shot 70-0 is preferably arranged in the center of the semiconductor wafer 7.

The controller 2 controls the wafer stage 18 to move the wafer 7 along the X-direction or Y-direction and controls the light source system 11 to emit light. In this way, the controller 2 makes the controlled section 1 to expose the shots 70 one by one.

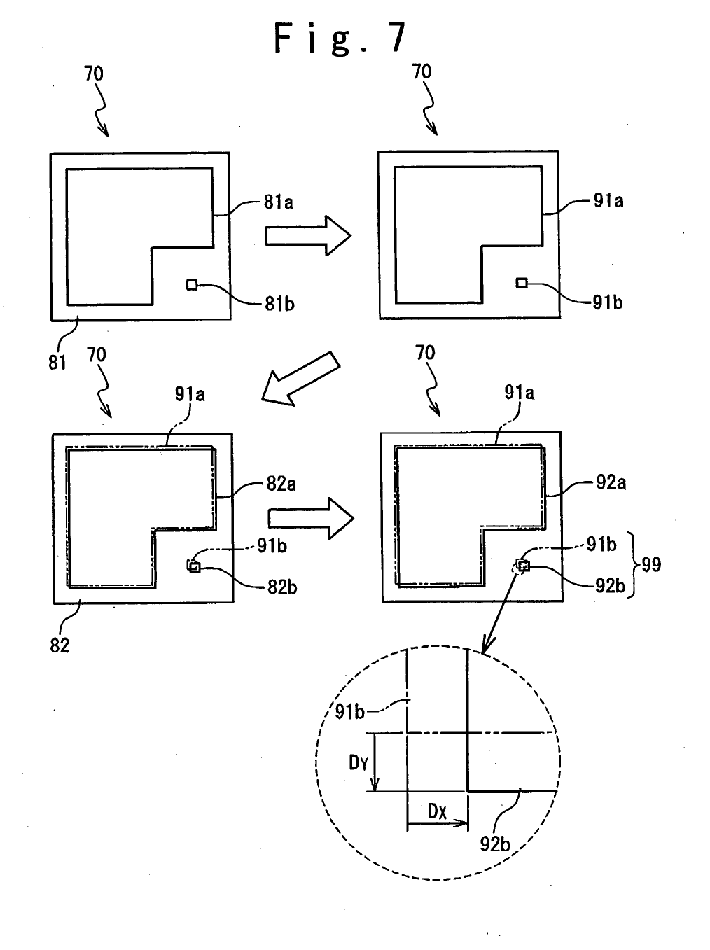

Referring to FIG. 7, a semiconductor device manufacturing method according to the present embodiment is described below. The semiconductor device manufacturing method includes a wafer processing step in which semiconductor elements and interconnections are formed in the semiconductor wafer 7. Each of interconnections connects one and another of the elements. The wafer processing step includes a step for forming a different identification mark 99 in each shot 70. A position in the semiconductor wafer 7 of the shot 70 which corresponds to each chip can be identified even after cutting of the semiconductor wafer 7, by forming the different identification mark 99 peculiar to each shot 70 based on a predetermined rule. FIG. 7 shows time series variation of one of the shots 70.

In the step for forming the identification marks according to the present embodiment, the pattern selector 14 arranges neither of the light-shielding plate 5 nor light-shielding plate 6 in the light path. Accordingly, the optical unit 10 projects whole of the mask pattern 30 onto the shot 70 at a timing and projects whole of the mask pattern 40 onto the shot 70 at a timing. The pattern selector 14 may be excluded from the semiconductor manufacturing apparatus 100 according to the present embodiment.

In the step for forming the identification marks, the controller 2 controls the optical unit 10 to expose the wafer 7 and controls the wafer stage 18 to move the wafer 7 along the X-direction or Y-direction. In this way, the semiconductor manufacturing apparatus 100 projects the mask pattern 30 and mask pattern 40 onto each shot 70.

The mask 3 is mounted to the mask stage 12 at beginning of the step for forming the identification marks. A resist film 81 is formed in each shot 70. The optical unit 10 exposes each shot 70 by projecting the mask pattern 30 onto the resist film 81 therein. In this exposure, an interconnection metal pattern 81a corresponding to the interconnection metal pattern 31 and identification pattern 81b corresponding to the identification pattern 32 are formed in the resist film 81. The interconnection metal pattern 81a and identification pattern 81b are geometrically similar to the interconnection metal pattern 31 and identification pattern 32, respectively.

Detailed descriptions are given below for the exposure of the shots 70 by using the mask pattern 30. The optical unit 10 exposes the shot 70-1 by projecting the mask pattern 30 onto the resist film 81. The wafer stage 18 moves the semiconductor wafer 7 in the X-direction with a distance of PX. The optical unit 10 exposes the shot 70-2 by projecting the mask pattern 30 to the resist film 81. By repeating such operations, the semiconductor manufacturing apparatus 100 exposes the row of the shots 70-1 to 70-3.

After the exposure of the shot 70-3, the wafer stage 18 moves the semiconductor wafer 7 in the Y-direction with a distance of PY.

The optical unit 10 exposes the shot 70-4 by projecting the mask pattern 30 onto the resist film 81. The wafer stage 18 moves the semiconductor wafer 7 in the reverse X-direction with a distance of PX. The optical unit 10 exposes the shot 70-5 by projecting the mask pattern 30 onto the resist film 81. By repeating such operations, the semiconductor manufacturing apparatus 100 exposes the row of the shots 70-4 to 70-6.

The semiconductor manufacturing apparatus 100 exposes the shots 70 one by one by using the mask pattern 30, as described above.

Next, an interconnection metal 91a corresponding to the interconnection metal pattern 81a and an identification metal 91b corresponding to the identification pattern 81b are formed at a time in each shot 70. Then, an interlayer dielectric film (not shown) is formed in each shot 70 and a resist film 82 is formed on or above the interlayer dielectric film.

Next, the mask 3 is replaced by the mask 4. The optical unit 10 exposes each shot 70 by projecting the mask pattern 40 onto the resist film 82 therein. In the exposure, an interconnection metal pattern 82a corresponding to the interconnection metal pattern 41 and a identification pattern 82b corresponding to the identification pattern 42 are formed in the resist film 82.

Detailed descriptions are given below for the exposure of the shots 70 by using the mask pattern 40. The optical unit 10 exposes the shot 70-1 by projecting the mask pattern 40 onto the resist film 82. The wafer stage 18 moves the wafer 7 in the X-direction with a distance of PX+d. The d is a unit of offset. The optical unit 10 exposes the shot 70-2 by projecting the mask pattern 40 onto the resist film 82. By repeating such operations, the semiconductor manufacturing apparatus 100 exposes the row of the shots 70-1 to 70-3.

After the exposure of the shot 70-3, the wafer stage 18 moves the wafer 7 in the Y-direction with a distance of PY+d.

The optical unit 10 exposes the shot 70-4 by projecting the mask pattern 40 onto the resist film 82. The wafer stage 18 moves the wafer 7 in the reverse X-direction with a distance of PX+d. The optical unit 10 exposes the shot 70-5 by projecting the mask pattern 40 onto the resist film 82. By repeating such operations, the semiconductor manufacturing apparatus 100 exposes the row of the shots 70-4 to 70-6.

The semiconductor manufacturing apparatus 100 expose the shots 70 one by one by using the mask pattern 40, as described above.

Next, an interconnection metal 92a corresponding to the interconnection metal pattern 82a and an identification metal 92b corresponding to the identification pattern 82b are formed in each shots 70 at a time. Then, an over coating film (not shown) is formed on or above the interconnection metal 92a and identification metal 92b.

In this way, the identification mark 99 which includes the identification metal 91b and identification metal 92b is formed in each shot 70. An X-offset in the X-direction of the identification metal 92b (identification pattern 82b) from the identification metal 91b (identification pattern 81b) is defined as DX. A Y-offset in the Y-direction of the identification metal 92b (identification pattern 82b) from the identification metal 91b (identification pattern 81b) is defined as DY.

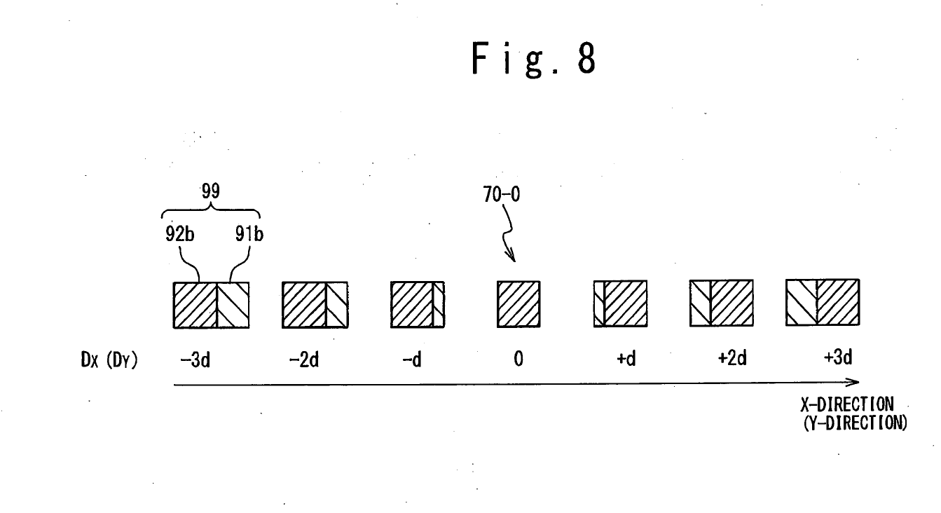

FIG. 8 is a plan view of the identification marks 99 formed in the shots 70 in the row along the X-direction (or in the column along the Y-direction). The DX in one shot 70 next to another shot 70 in the X-direction is greater than the DX of the other shot 70 by the unit of offset d. The DY in one shot 70 next to another shot 70 in the Y-direction is greater than the DY of the other shot 70 by the unit of offset d. Those are true for each pair of shots 70 next to each other along the X-direction or Y-direction. The offset (DX, DY) in the identification mark 99 in the shot 70-0 is (0, 0). Therefore, based on the offset (DX, DY) in the identification mark 99 in each chip, the position in the wafer 7 of the shot 70 corresponding to the chip can be identified.

The overlapping between the identification metals 91b and 92b as shown in FIG. 8 is preferable for sensing the offset (DX, DY) in the identification mark 99.

In the step for forming the identification marks according to the present embodiment, the same offset (DX, DY) occurs between the interconnection metal 91a and interconnection metal 92a in the shot 70. The magnitude of the unit of offset d is set such that the magnitudes of DX and DY in any chip are in an acceptable range for the product including the chip. In this case, the offset between the interconnection metal 91a and interconnection metal 92a does not deteriorate the quality of the product. The interconnection metal 92a and identification metal 92b are preferably formed in a layer above another layer in which the interconnection metal 91a and identification metal 91b are arranged, since a restriction on the offset is not tight in an upper layer in the chip.

In the present embodiment, the exposure by using the mask pattern 40 may be executed as follows.

The optical unit 10 exposes the shot 70-1 by projecting the mask pattern 40 onto the resist film 82. The wafer stage 18 moves the semiconductor wafer 7 in the X-direction with a distance of PX−d. The optical unit 10 exposes the shot 70-2 by projecting the mask pattern 40 onto the resist film 82. By repeating such operations, the semiconductor manufacturing apparatus 100 exposes the row of the shots 70-1 to 70-3.

After the exposure of the shot 70-3, the wafer stage 18 moves the semiconductor wafer 7 in the Y-direction with a distance of PY−d.

The optical unit 10 exposes the shot 70-4 by projecting the mask pattern 40 onto the resist film 82. The wafer stage 18 moves the wafer 7 in the reverse X-direction with a distance of PX−d. The optical unit 10 exposes the shot 70-5 by projecting the mask pattern 40 onto the resist film 82. By repeating such operations, the semiconductor manufacturing apparatus 100 exposes the row of the shots 70-4 to 70-6.

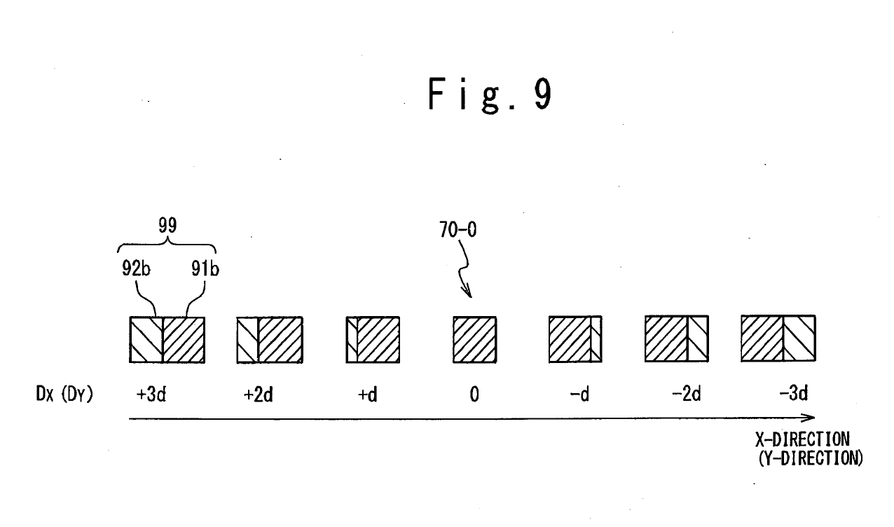

FIG. 9 is a plan view of the identification marks 99 in this case. The DX in one shot 70 next to another shot 70 in the X-direction is smaller than the DX of the other shot 70 by the unit of offset d. The DY in one shot 70 next to another shot 70 in the Y-direction is smaller than the DY of the other shot 70 by the unit of offset d. Those are true for each pair of shots 70 next to each other along the X-direction or Y-direction. The offset (DX, DY) in the identification mark 99 in the shot 70-0 is (0, 0). Therefore, based on the offset (DX, DY) in the identification mark 99 in each chip, the position in the semiconductor wafer 7 of the shot 70 corresponding to the chip can be identified.

### Second Embodiment

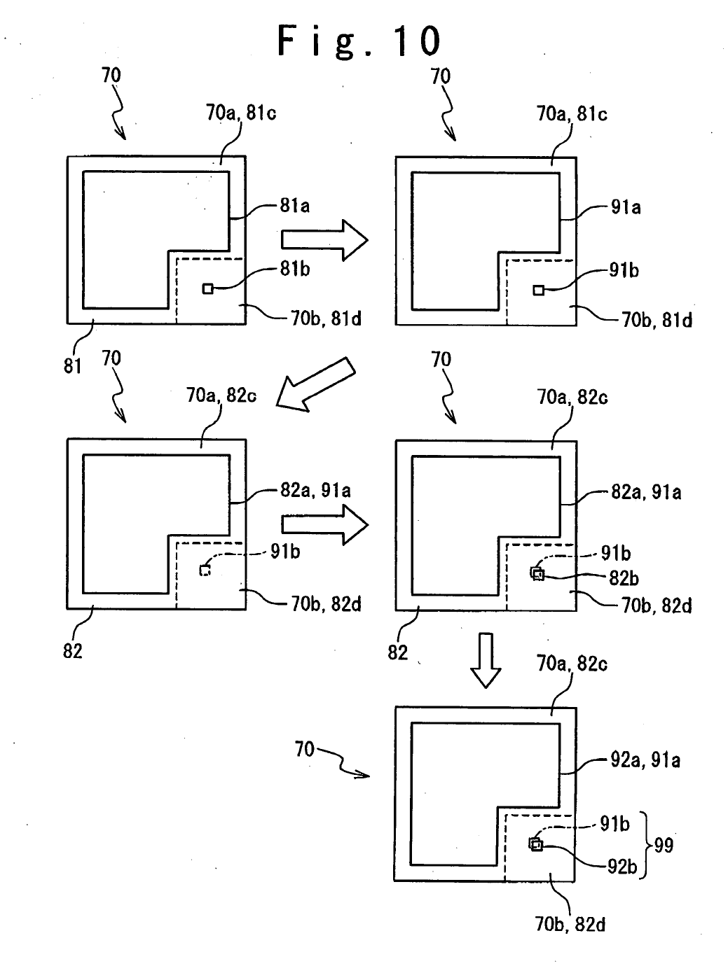

Referring to the FIG. 10, a semiconductor device manufacturing method according to a second embodiment of the present invention is described below. The semiconductor manufacturing apparatus 100 is used in the method. The semiconductor device manufacturing method includes a wafer processing step. The wafer processing step includes a step for forming a different identification mark 99 in each shot 70. A position in the semiconductor wafer 7 of the shot 70 which corresponds to each chip can be identified even after cutting of the semiconductor wafer 7, by forming the different identification mark 99 peculiar to each shot 70 based on a predetermined rule. FIG. 10 shows time series variation of one of the shots 70.

In the step for forming the identification marks, the controller 2 controls the optical unit 10 to expose the wafer 7 and controls the wafer stage 18 to move the wafer 7 along the X-direction or Y-direction. In this way, the semiconductor manufacturing apparatus 100 projects the mask pattern 30 and mask pattern 40 onto each shot 70. In this step, the pattern selector 14 selects the pattern to be projected by the optical unit 10.

The mask 3 is mounted to the mask stage 12 at beginning of the step for forming the identification marks. The pattern selector 14 arranges neither the light-shielding plate 5 nor light-shielding plate 6 in the optical path. The semiconductor manufacturing apparatus 100 exposes the shots 70 one by one by using the mask pattern 30 as described in the first embodiment.

In the exposure of the shots 70 by using the mask pattern 30, the interconnection metal pattern 81a and identification pattern 81b are formed in a first portion 81c and second portion 81d of the resist film 81, respectively. The first portion 81c is arranged in a first portion 70a of the shot 70. The second portion 81d is arranged in a second portion 70b of the shot 70.

Next, an interconnection metal 91a corresponding to the interconnection metal pattern 81a and an identification metal 91b corresponding to the identification pattern 81b are formed at a time in each shot 70. The interconnection metal 91a and identification metal 91b are formed simultaneously in each shot 70. Then, an interlayer dielectric film (not shown) is formed in each shot 70 and a resist film 82 is formed on or above the interlayer dielectric film.

Next, the mask 3 is replaced by the mask 4. The optical unit 10 exposes each shot 70 by projecting the mask pattern 40 onto the resist film 82 therein.

Detailed descriptions are given below for the exposure of the shots 70 by using the mask pattern 40.

When the pattern selector 14 arranges the light-shielding plate 5 in the optical path, the optical unit 10 exposes the shot 70-1 by projecting the interconnection metal pattern 41 onto a first portion 82c of the resist film 82. The first portion 82c is arranged in the first portion 70a. In this exposure, the light passing through the first region 4a passes through the translucent portion 5a. On the other hand, the light passing through the second region 4b is screened by the light-shielding portion 5b. Thus, the interconnection metal pattern 82a is formed in the first portion 82c but the identification pattern 82b is not formed in a second portion 82d of the resist film 82 in this exposure. The second portion 82d is arranged in the second portion 70b.

The wafer stage 18 moves the semiconductor wafer 7 in the reverse X-direction with a distance of LX1 (LX1=3d) and in the reverse Y-direction with a distance of LY1 (LY1=d). When the pattern selector 14 arranges the light-shielding plate 6 in the optical path, the optical unit 10 exposes the shot 70-1 by projecting the identification pattern 42 onto the second portion 82d. In this exposure, the light passing through the second region 4b passes through the translucent portion 6a. On the other hand, the light passing through the first region 4a is screened by the light-shielding portion 6b. Thus, the identification pattern 82b is formed in the second portion 82d but the interconnection metal pattern 82a is not formed in the first portion 82c in this exposure. Thus, a double projection of the interconnection metal pattern 41 onto the first portion 82c is prevented.

The wafer stage 18 moves the semiconductor wafer 7 in the X-direction with a distance of PX+LX1 and in the Y-direction with a distance of LY1. When the pattern selector 14 arranges the light-shielding plate 5 in the optical path, the optical unit 10 exposes the shot 70-2 by projecting the interconnection metal pattern 41 onto the first portion 82c.

The wafer stage 18 moves the semiconductor wafer 7 in the reverse X-direction with a distance of LX2 (LX2=LX1−d) and in the reverse Y-direction with a distance of LY1. When the pattern selector 14 arranges the light-shielding plate 6 in the optical path, the optical unit 10 exposes the shot 70-2 by projecting the identification pattern 42 onto the second portion 82d.

By repeating such operations, the semiconductor manufacturing apparatus 100 exposes the row of the shots 70-1 to 70-3.

After the exposure of the shot 70-3, the wafer stage 18 moves the semiconductor wafer 7 in the X-direction with a distance of LX3 (LX3=LX1−6d) and in the Y-direction with a distance of PY+LY1. Since the shot 70-3 is a sixth shot from the shot 70-1 in the reverse X-direction, the distance of movement in the X-direction is LX1−6d.

When the pattern selector 14 arranges the light-shielding plate 5 in the optical path, the optical unit 10 exposes the shot 70-4 by projecting the interconnection metal pattern 41 onto the first portion 82c.

The wafer stage 18 moves the semiconductor wafer 7 in the X-direction with a distance of LX4 (LX4=−LX3) and in the Y-direction with a distance of LY2 (LY2=LY1−d). When the pattern selector 14 arranges the light-shielding plate 6 in the optical path, the optical unit 10 exposes the shot 70-4 by projecting the identification pattern 42 onto the second portion 82d.

The wafer stage 18 moves the semiconductor wafer 7 in the reverse X-direction with a distance of PX+LX4 and in the reverse Y-direction with a distance of LY2. When the pattern selector 14 arranges the light-shielding plate 5 in the optical path, the optical unit 10 exposes the shot 70-5 by projecting the interconnection metal pattern 41 onto the first portion 82c.

The wafer stage 18 moves the semiconductor wafer 7 in the X-direction with a distance of L5 (L5=L4−d) and in the Y-direction with a distance of LY2. When the pattern selector 14 arranges the light-shielding plate 6 in the optical path, the optical unit 10 exposes the shot 70-5 by projecting the identification pattern 42 onto the second portion 82d.

By repeating such operations, the semiconductor manufacturing apparatus 100 exposes the row of the shots 70-4 to 70-6.

The semiconductor manufacturing apparatus 100 exposes the shots 70 one by one by using the mask pattern 40, as described above.

Next, an interconnection metal 92a corresponding to the interconnection metal pattern 82a and an identification metal 92b corresponding to the identification pattern 82b are formed at a time in each shot 70. The interconnection metal 92a and identification metal 92b are formed simultaneously in each shot 70. In this way, the identification mark 99 which includes the identification metal 91b and identification metal 92b is formed in each shot 70. After the formation of the identification mark 99, an over coating film (not shown) is formed on or above the interconnection metal 92a and identification metal 92b.

FIG. 8 is a plan view of the identification marks 99 formed in the step according to the second embodiment. The DX in one shot 70 next to another shot 70 in the X-direction is greater than the DX of the other shot 70 by the unit of offset d. The DY in one shot 70 next to another shot 70 in the Y-direction is greater than the DY of the other shot 70 by the unit of offset d. Those are true for each pair of shots 70 next to each other along the X-direction or Y-direction. The offset (DX, DY) in the identification mark 99 in the shot 70-0 is (0, 0). Therefore, based on the offset (DX, DY) in the identification mark 99 in each chip, the position in the wafer 7 of the shot 70 corresponding to the chip can be identified.

In the present embodiment, an offset between the interconnection metal 91a and interconnection metal 92a can be zero in all shots 70. Therefore, the step for forming the identification marks according to the present embodiment is preferable when the wafer 7 is cut into large number of chips.

In the present embodiment, the exposure by using the mask pattern 40 may be executed as follows.

When the pattern selector 14 arranges the light-shielding plate 5 in the optical path, the optical unit 10 exposes the shot 70-1 by projecting the interconnection metal pattern 41 onto the first portion 82c.

The wafer stage 18 moves the semiconductor wafer 7 in the reverse X-direction with a distance of LX1′ (LX1′=−3d) and in the reverse Y-direction with a distance of LY1′ (LY1′=−d). When the pattern selector 14 arranges the light-shielding plate 6 in the optical path, the optical unit 10 exposes the shot 70-1 by projecting the identification pattern 42 onto the second portion 82d.

The wafer stage 18 moves the semiconductor wafer 7 in the X-direction with a distance of PX+LX1′ and in the Y-direction with a distance of LY1′. When the pattern selector 14 arranges the light-shielding plate 5 in the optical path, the optical unit 10 exposes the shot 70-2 by projecting the interconnection metal pattern 41 onto the first portion 82c.

The wafer stage 18 moves the semiconductor wafer 7 in the reverse X-direction with a distance of LX2′ (LX2′=LX1′+d) and in the reverse Y-direction with a distance of LY1′. When the pattern selector 14 arranges the light-shielding plate 6 in the optical path, the optical unit 10 exposes the shot 70-2 by projecting the identification pattern 42 onto the second portion 82d.

By repeating such operations, the semiconductor manufacturing apparatus 100 exposes the row of the shots 70-1 to 70-3.

After the exposure of the shot 70-3, the wafer stage 18 moves the semiconductor wafer 7 in the X-direction with a distance of LX3′ (LX3′−LX1′+6d) and in the Y-direction with a distance of PY+LY1′. Since the shot 70-3 is the sixth shot from the shot 70-1 in the reverse X-direction, the distance of movement in the X-direction is LX1′+6d.

When the pattern selector 14 arranges the light-shielding plate 5 in the optical path, the optical unit 10 exposes the shot 70-4 by projecting the interconnection metal pattern 41 onto the first portion 82c.

The wafer stage 18 moves the semiconductor wafer 7 in the X-direction with a distance of LX4′ (LX4′=−LX3′) and in the Y-direction with a distance of LY2′ (LY2′=LY1′−d). When the pattern selector 14 arranges the light-shielding plate 6 in the optical path, the optical unit 10 exposes the shot 70-4 by projecting the identification pattern 42 onto the second portion 82d.

The wafer stage 18 moves the semiconductor wafer 7 in the reverse X-direction with a distance of PX+LX4′ and in the reverse Y-direction with a distance of LY2′. When the pattern selector 14 arranges the light-shielding plate 5 in the optical path, the optical unit 10 exposes the shot 70-5 by projecting the interconnection metal pattern 41 onto the first portion 82c.

The wafer stage 18 moves the semiconductor wafer 7 in the X-direction with a distance of LX5′ (LX5′=LX4′+d) and in the Y-direction with a distance of LY2′. When the pattern selector 14 arranges the light-shielding plate 6 in the optical path, the optical unit 10 exposes the shot 70-5 by projecting the identification pattern 42 onto the second portion 82d.

By repeating such operations, the semiconductor manufacturing apparatus 100 exposes the row of the shots 70-4 to 70-6.

FIG. 9 is a plan view of the identification marks 99 in this case. The DX in one shot 70 next to another shot 70 in the X-direction is smaller than the DX of the other shot 70 by the unit of offset d. The DY in one shot 70 next to another shot 70 in the Y-direction is smaller than the DY of the other shot 70 by the unit of offset d. Those are true for each pair of shots 70 next to each other along the X-direction or Y-direction. The offset (DX, DY) in the identification mark 99 in the shot 70-0 is (0, 0). Therefore, based on the offset (DX, DY) in the identification mark 99 in each chip, the position in the semiconductor wafer 7 of the shot 70 corresponding to the chip can be identified.

By forming the different identification marks 99 in the shots 70 based on the predetermined rule described above, the direction and magnitude of the offset between the identification metals 91b and 92b in each chip correspond to the direction and magnitude of a vector from the reference shot 70 such as shot 70-0 to the shot 70 corresponding to the chip. Even in the case that a precise position of the shot can not be identified, an approximate position of the shot can be identified.

In the above embodiments, the identification mark 99 is preferably formed in a vacant portion, such as second portion 70b, arranged in a corner of the shot 70. No or small number of semiconductor elements are formed in the vacant portion.

The semiconductor manufacturing apparatus 100 may be one including a fixed wafer stage 18 and movable optical unit 10.

It is apparent that the present invention is not limited to the above embodiments, but may be modified and changed without departing from the scope and spirit of the invention.

What is claimed is:

1. A semiconductor manufacturing apparatus comprising:
a controller;
a wafer stage configured to move a semiconductor wafer; and
an optical unit,
wherein said optical unit is configured to expose a first resist film in each of shots of said semiconductor wafer by using a first mask pattern and to expose a second resist film in said shot by using a second mask pattern,
said first mask pattern includes a first interconnection mask pattern and a first identification mask pattern,
said second mask pattern includes a second interconnection mask pattern and a second identification mask pattern,
a first interconnection metal pattern corresponding to said first interconnection mask pattern and a first identification pattern corresponding to said first identification mask pattern are formed in said first resist film,
a second interconnection metal pattern corresponding to said second interconnection mask pattern and a second identification pattern corresponding to said second identification mask pattern are formed in said second resist film, and
said controller is configured to control said wafer stage and said optical unit such that an offset between said first identification pattern and said second identification pattern is different among said shots based on a predetermined rule.

2. The semiconductor manufacturing apparatus according to claim 1, wherein said optical unit is configured to project said second interconnection mask pattern while not projecting said second identification mask pattern onto said second resist film at a timing and to project said second identification mask pattern while not projecting said second interconnection mask pattern onto said second resist film at another timing.

3. The semiconductor manufacturing apparatus according to claim 1, wherein said shots includes a first shot, second shot next to said first shot in a X-direction and third shot next to said first shot in a Y-direction,
said offset is represented by a combination of a X-offset in said X-direction and a Y-offset in said Y-direction,
said X-offset in said first shot is defined as DX1,
said Y-offset in said first shot is defined as DY1,
said X-offset in said second shot is defined as DX2,
said Y-offset in said second shot is defined as DY2,
said X-offset in said third shot is defined as DX3,
said Y-offset in said third shot is defined as DY3,
a first difference obtained by subtracting said DX1 from said DX2 is defined as d1,
a second difference obtained by subtracting said DY1 from said DY3 is defined as d2, and
said predetermined rule prescribes that said DY2 is equal to said DY1, that said DX3 is equal to said DX1, that said d1 is equal to said d2 and that said d1 is a positive or negative constant.

4. The semiconductor manufacturing apparatus according to claim 1, wherein said first interconnection metal pattern corresponds to a lower layer interconnection metal,
said second interconnection metal pattern corresponds to an upper layer interconnection metal.

5. A semiconductor device manufacturing method comprising:
exposing a first resist film in each of shots of a semiconductor wafer by using a first mask pattern; and
exposing a second resist film in said shot by using a second mask pattern,
wherein said first mask pattern includes a first interconnection mask pattern and a first identification mask pattern,
said second mask pattern includes a second interconnection mask pattern and a second identification mask pattern,
a first interconnection metal pattern corresponding to said first interconnection mask pattern and a first identification pattern corresponding to said first identification mask pattern are formed in said first resist film in said exposing said first resist film,
a second interconnection metal pattern corresponding to said second interconnection mask pattern and a second identification pattern corresponding to said second identification mask pattern are formed in said second resist film in said exposing said second resist film, and
an offset between said first identification pattern and said second identification pattern is different among said shots based on a predetermined rule.

6. The semiconductor device manufacturing method according to claim 5, wherein said exposing said second resist film comprises:
projecting said second interconnection mask pattern while not projecting said second identification mask pattern onto said second resist film at a timing; and
projecting said second identification mask pattern while not projecting said second interconnection mask pattern onto said second resist film at another timing.

7. The semiconductor device manufacturing method according to claim 5, wherein said shots includes a first shot, second shot next to said first shot in a X-direction and third shot next to said first shot in a Y-direction,
said offset is represented by a combination of a X-offset in said X-direction and Y-offset in said Y-direction,
said X-offset in said first shot is defined as DX1,
said Y-offset in said first shot is defined as DY1,
said X-offset in said second shot is defined as DX2,
said Y-offset in said second shot is defined as DY2,
said X-offset in said third shot is defined as DX3,
said Y-offset in said third shot is defined as DY3,
a first difference obtained by subtracting said DX1 from said DX2 is defined as d1,
a second difference obtained by subtracting said DY1 from said DY3 is defined as d2, and
said predetermined rule prescribes that said DY2 is equal to said DY1, that said DX3 is equal to said DX1, that said d1 is equal to said d2 and that said d1 is a positive or negative constant.

8. The semiconductor device manufacturing method according to claim 5, wherein said first interconnection metal pattern corresponds to a lower layer interconnection metal,
said second interconnection metal pattern corresponds to an upper layer interconnection metal.

9. The semiconductor device manufacturing method according to claim 5, further comprising:
forming a first interconnection metal corresponding to said first interconnection metal pattern and a first identification metal corresponding to said first identification pattern at a time;
forming a second interconnection metal corresponding to said second interconnection metal pattern and a second identification metal corresponding to said second identification pattern at a time; and
forming a interlayer dielectric film in said semiconductor wafer,
wherein said forming said interlayer dielectric film is performed between said forming said first interconnection metal and said forming said second interconnection metal.

10. A semiconductor manufacturing apparatus comprising:
a means for moving a semiconductor wafer;
a means for exposing said semiconductor wafer; and
a means for controlling said means for moving and said means for exposing,
wherein said means for exposing is configured to expose a first resist film in each of shots of said semiconductor wafer by using a first mask pattern and to expose a second resist film in said shot by using a second mask pattern,
said first mask pattern includes a first interconnection mask pattern and a first identification mask pattern,
said second mask pattern includes a second interconnection mask pattern and a second identification mask pattern,
a first interconnection metal pattern corresponding to said first interconnection mask pattern and a first identification pattern corresponding to said first identification mask pattern are formed in said first resist film,
a second interconnection metal pattern corresponding to said second interconnection mask pattern and a second identification pattern corresponding to said second identification mask pattern are formed in said second resist film, and
said means for controlling is configured to control said means for moving and said means for exposing such that an offset between said first identification pattern and said second identification pattern is different among said shots based on a predetermined rule.

11. The semiconductor manufacturing apparatus according to claim 10, wherein said means for exposing is configured to project said second interconnection mask pattern while not projecting said second identification mask pattern onto said second resist film at a timing and to project said second identification mask pattern while not projecting said second interconnection mask pattern onto said second resist film at another timing.

12. The semiconductor manufacturing apparatus according to claim 10, wherein said shots includes a first shot, second shot next to said first shot in a X-direction and third shot next to said first shot in a Y-direction,
said offset is represented by a combination of a X-offset in said X-direction and a Y-offset in said Y-direction,
said X-offset in said first shot is defined as DX1,
said Y-offset in said first shot is defined as DY1,
said X-offset in said second shot is defined as DX2,
said Y-offset in said second shot is defined as DY2,
said X-offset in said third shot is defined as DX3,
said Y-offset in said third shot is defined as DY3,
a first difference obtained by subtracting said DX1 from said DX2 is defined as d1,
a second difference obtained by subtracting said DY1 from said DY3 is defined as d2, and
said predetermined rule prescribes that said DY2 is equal to said DY1, that said DX3 is equal to said DX1, that said d1 is equal to said d2 and that said d1 is a positive or negative constant.

13. The semiconductor manufacturing apparatus according to claim 10, wherein said first interconnection metal pattern corresponds to a lower layer interconnection metal,
said second interconnection metal pattern corresponds to an upper layer interconnection metal.
